(19) United States
(12) Patent Application Publication
(10) Pub. No.: US 2025/0385202 A1
(43) Pub. Date: Dec. 18, 2025

(54) SEMICONDUCTOR DEVICE AND A MANUFACTURING METHOD OF THE SEMICONDUCTOR DEVICE

(71) Applicant: Samsung Electronics Co., Ltd., Suwon-si (KR)

(72) Inventors: Jeong Wan HAN, Suwon-si (KR); Jeong Hun KIM, Suwon-si (KR); Pyo Jin JEON, Suwon-si (KR); Tae-Hong KIM, Suwon-si (KR)

(73) Assignee: Samsung Electronics Co., Ltd., Suwon-si (KR)

(21) Appl. No.: 19/051,297

(22) Filed: Feb. 12, 2025

(30) Foreign Application Priority Data
Jun. 17, 2024 (KR) 10-2024-0078022

(51) Int. Cl. H01L 23/00; H01L 23/528; H01L 23/532

(52) U.S. Cl. CPC H01L 24/02; H01L 23/5283; H01L 23/53228; H01L 23/53295; H01L 24/16; H01L 2224/02311; H01L 2224/02313; H01L 2224/02331; H01L 2224/02381; H01L 2224/0239; H01L 2224/024; H01L 2224/16111; H01L 2924/30101

(57) ABSTRACT

A manufacturing method of a semiconductor device includes forming a conductive wiring including a stack of a metal layer and a wiring capping layer on a substrate, forming an insulating film structure that to surround upper and side faces of the conductive wiring, forming a first mask pattern including a first opening on the insulating film structure to overlap the conductive wiring in a vertical direction, forming a first trench to expose the wiring capping layer in using the first mask pattern, removing the exposed wiring capping layer using wet etching to expose at least a part of the metal layer, forming a redistribution conductive wiring, which includes a pad region and a wiring region, the pad region covering the exposed metal layer, and a wiring region extending along a side wall of the first trench and the upper face of the insulating film structure.

### CROSS-REFERENCE TO RELATED APPLICATION

This application claims priority from Korean Patent Application No. 10-2024-0078022 filed on Jun. 17, 2024 in the Korean Intellectual Property Office, and all the benefits accruing therefrom under 35 U.S.C. 119, the contents of which in its entirety are herein incorporated by reference.

### BACKGROUND

### 1. Field

The present inventive concepts relate to semiconductor devices and/or manufacturing methods of the semiconductor device.

### 2. Description of the Related Art

Due to the development of the electronics industry, there is an increasing demand for higher functionality, higher speed, and smaller size of electronic components. Therefore, while higher integration of a semiconductor device is being required, widths of wirings in the semiconductor device becomes narrower, and redistribution also becomes difficult to be formed on the wirings.

Research for reducing generation of nitride-based etching residues during etching for forming a via and/or for facilitating the removal of the generated etching residues is being conducted. A slope generated when etching for forming the via may be formed to be nearly vertical, by reducing the generation of etching residues and/or facilitating the removal of the generated etching residues.

### SUMMARY

Some example embodiments of the present inventive concepts provide manufacturing methods of a semiconductor device that may improve element performance and reliability.

Some example embodiment of the present inventive concepts also provide a semiconductor device that may improve element performance and reliability.

According to an example embodiment of the present disclosure, a manufacturing method of a semiconductor device includes forming a conductive wiring on a substrate in a first direction, the conductive wiring including a metal layer and a wiring capping layer that are stacked sequentially, forming an insulating film structure to surround an upper face and a side face of the conductive wiring, forming a first mask pattern including a first opening on the insulating film structure, the first opening overlapping the conductive wiring in a vertical direction, forming a first trench to expose the wiring capping layer in the insulating film structure, using the first mask pattern as a mask, removing the exposed wiring capping layer using wet etching to expose at least a part of the metal layer, forming a redistribution conductive wiring, the redistribution conductive wiring including a pad region and a wiring region, the pad region covering the part of the metal layer exposed in the removing, a wiring region extending along a side wall of the first trench and the upper face of the insulating film structure, forming a second mask pattern including a second opening on the redistribution conductive wiring, the second opening exposing a part of the wiring region of the redistribution conductive wiring, and etching the part of the wiring region of the redistribution conductive wiring exposed by the second opening to form a second trench in the redistribution conductive wiring.

According to an example embodiment of the present disclosure, a semiconductor device includes a substrate, a conductive wiring on the substrate, an insulating film structure on the substrate, the insulating film structure surrounding an upper face and a side face of the conductive wiring, a first trench in the insulating film structure, the first trench exposing at least a part of the conductive wiring, a first redistribution conductive wiring extending along the upper face of the conductive wiring, and a second redistribution conductive wiring extending along a side wall of the first trench and an upper face of the insulating film structure, wherein the first redistribution conductive wiring includes a convex shape in a direction toward the conductive wiring.

According to an example embodiment of the present disclosure, a manufacturing method of a semiconductor device includes forming a conductive wiring on a substrate in the first direction, the conductive wiring including a metal layer and a wiring capping layer that are sequentially stacked on a substrate in the first direction, forming an insulating film structure to surround an upper face and a side face of the conductive wiring, forming a first mask pattern including a first opening on the insulating film structure, the first opening overlapping the conductive wiring in a vertical direction, forming a first trench to expose the wiring capping layer inside the insulating film structure, using the first mask pattern as a mask, removing the first mask pattern, forming a redistribution barrier film extending along a side wall of the first trench and the upper face of the insulating film structure, removing the exposed wiring capping layer using wet etching to expose at least a part of the metal layer, forming a redistribution conductive wiring, the redistribution conductive wiring including a pad region and a wiring region, the pad region covering the part of the metal layer exposed in the removing the exposed wiring capping layer, the wiring region extending along the side wall of the first trench and the upper face of the insulating film structure, forming a second mask pattern including a second opening on the redistribution conductive wiring, the second opening exposing a part of the wiring region of the redistribution conductive wiring, etching the part of the wiring region of the redistribution conductive wiring exposed in the forming the second mask pattern to form a second trench in the redistribution conductive wiring, and removing the second mask pattern.

However, aspects of the present inventive concepts are not restricted to the one set forth herein. The above and other aspects of the present inventive concepts will become more apparent to one of ordinary skill in the art to which the present inventive concepts pertains by referencing the detailed description of some example embodiments given below.

### BRIEF DESCRIPTION OF DRAWINGS

The above and other aspects and features of the present disclosure will become more apparent by describing in detail illustrative some example embodiments thereof with reference to the attached drawings, in which:

FIG. 1 is a plan view for explaining a semiconductor device according to an example embodiment of the present inventive concepts.

FIG. 2 is a cross-sectional view of the semiconductor device of FIG. 1 taken along line A-A′.

FIG. 3 is an enlarged view of a R2 region of FIG. 2.

FIGS. 4 to 11 are diagrams for explaining intermediate stages of a method for manufacturing a semiconductor device according to an example embodiment of the present inventive concepts.

### DETAILED DESCRIPTION

Although terms such as first and second are used to describe various elements or components in the present specification, it goes without saying that these elements or components are not limited by these terms. These terms are only used to distinguish a single element or component from other elements or components. Therefore, it goes without saying that a first element or component referred to below may be a second element or component within the present inventive concepts.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

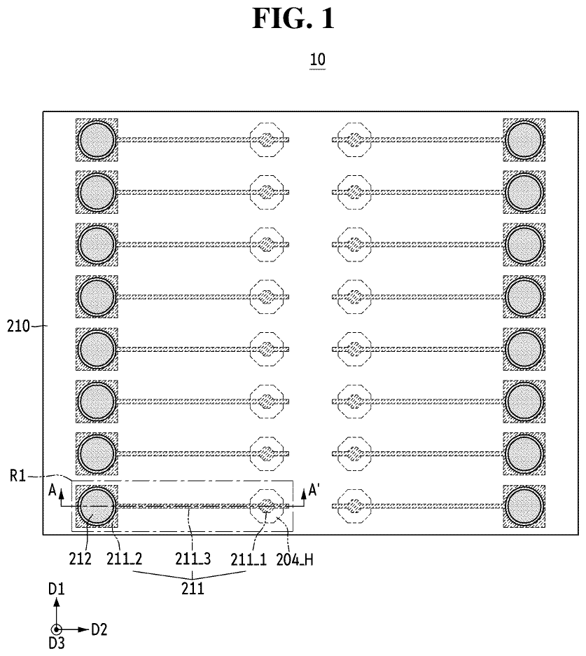

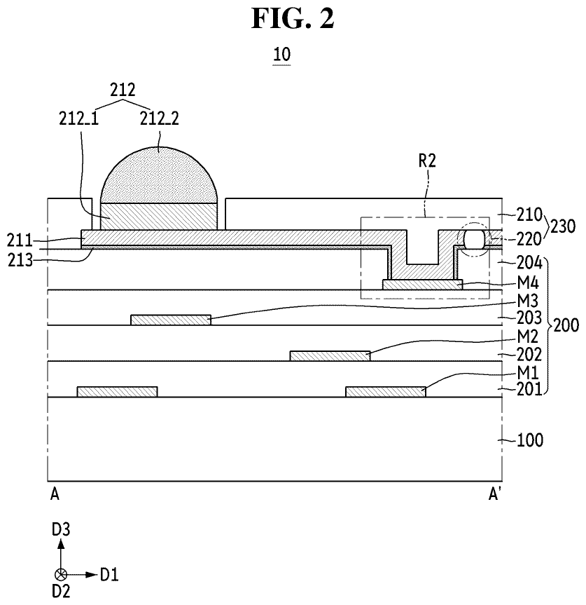

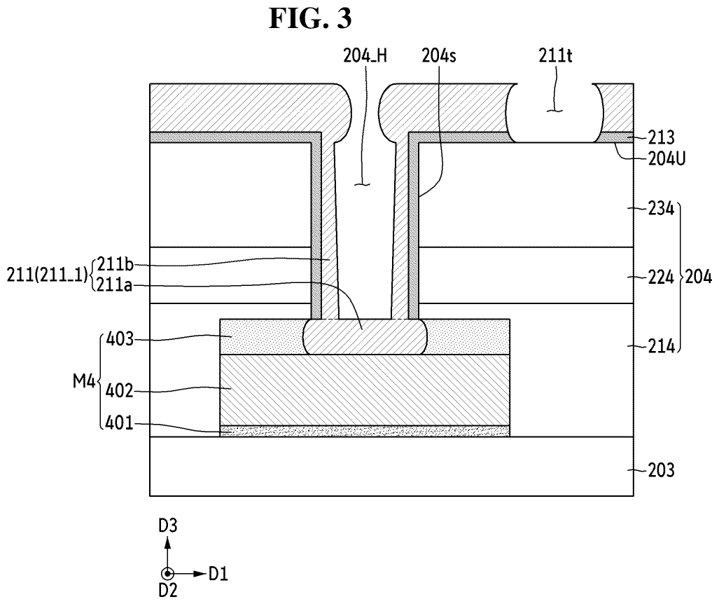

FIG. 1 is a plan view for explaining a semiconductor device according to an example embodiment of the present inventive concepts. FIG. 2 is a cross-sectional view of the semiconductor device of FIG. 1 taken along line A-A′. FIG. 3 is an enlarged view of a R2 region of FIG. 2.

Referring to FIGS. 1 to 3, a semiconductor device 10 according to an example embodiment of the present inventive concepts may include a substrate 100, a wiring layer 200, a passivation layer 230, a redistribution conductive layer 211, and a redistribution bump 212.

The substrate 100 may be bulk silicon or silicon-on-insulator (SOI). In some example embodiments, the substrate 100 may be a silicon substrate, or may include other materials, for example, but not limited to, silicon germanium, silicon germanium on insulator (SGOI), indium antimonide, lead telluride, indium arsenide, indium phosphide, gallium arsenide or gallium antimonide.

Although not shown, the substrate 100 may include various internal circuit elements. The internal circuit elements may include an active element such as a transistor, a passive element such as a resistance and a capacitor, a contact/through electrode (through silicon via), or the like.

The wiring layer 200 may include first to fourth insulating film structures 201 to 204 and first to fourth conductive wirings M1 to M4. The first to fourth insulating film structures 201 to 204 may be sequentially stacked in a third direction D3. The third direction D3 is a direction perpendicular to the substrate 100.

A first insulating film structure 201 may be formed on the substrate 100. Although the first insulating film structure 201 is shown as being formed directly on the substrate 100, this is only for convenience of explanation. It goes without saying that, for example, other interlayer insulating films and/or conductive patterns may be interposed between the substrate 100 and the first insulating film structure 201.

The first insulating film structure 201 may include, for example, at least one of silicon oxide, silicon nitride, silicon oxynitride, a low-k material having a dielectric constant lower than that of silicon oxide, or a combination thereof. The low-k material may include, but not limited to, at least one of FOX (Flowable Oxide), TOSZ (Torene SilaZene), USG (Undoped Silica Glass), BSG (Borosilica Glass), PSG (PhosphoSilica Glass), BPSG (BoroPhosphoSilica Glass), PETEOS (Plasma Enhanced Tetra Ethyl Ortho Silicate), FSG (Fluoride Silicate Glass), CDO (Carbon Doped silicon Oxide), Xerogel, Aerogel, Amorphous Fluorinated Carbon, OSG (Organo Silicate Glass), Parylene, BCB (bis-benzocyclobutenes), SiLK, polyimide, porous polymeric material, or combinations thereof.

A first conductive wiring M1 may be formed in the first insulating film structure 201. For example, the first conductive wiring M1 may extend in a first direction D1 or a second direction D2. The first direction D1 or the second direction D2 may be a direction that is parallel to an upper face of the substrate 100. Accordingly, the first conductive wiring M1 may extend long inside the first insulating film structure 201. Although not shown, a via may be formed on the first conductive wiring M1 to electrically connect the first conductive wiring M1 to a second conductive wiring M2 as described below.

The first conductive wiring M1 may include a conductive material. For example, the first conductive wiring M1 may include, but not limited to, one or more metals such as tungsten (W), titanium (Ti), tantalum (Ta), copper (Cu), and/or aluminum (Al). For convenience of explanation, the following description will be given assuming that the first conductive wiring M1 includes copper (Cu).

Although not shown, the first conductive wiring M1 may be connected to various internal circuit elements inside the substrate 100. Thus, the first conductive wiring M1 may be used to configure a circuit of the semiconductor device 10 according to some example embodiments.

The second insulating film structure 202 may be formed on the first insulating film structure 201 and the first conductive wiring M1. Although the second insulating film structure 202 is shown as being formed directly on the first insulating film structure 201, this is only for convenience of explanation. Of course, for example, other etch stop films and/or conductive patterns may be interposed between the second insulating film structure 202 and the first insulating film structure 201.

The second insulating film structure 202 may include, for example, at least one of silicon oxide, silicon nitride, silicon oxynitride, a low dielectric constant material having a dielectric constant lower than that of silicon oxide, or combinations thereof. The low dielectric constant material may include, but not limited to, at least one of FOX (Flowable Oxide), TOSZ (Torene SilaZene), USG (Undoped Silica Glass), BSG (Borosilica Glass), PSG (PhosphoSilica Glass), BPSG (BoroPhosphoSilica Glass), PETEOS (Plasma Enhanced Tetra Ethyl Ortho Silicate), FSG (Fluoride Silicate Glass), CDO (Carbon Doped silicon Oxide), Xerogel, Aerogel, Amorphous Fluorinated Carbon, OSG (Organo Silicate Glass), Parylene, BCB (bis-benzocyclobutenes), SiLK, polyimide, porous polymeric material, or combinations thereof.

The second conductive wiring M2 may be formed in the second insulating film structure 202. For example, the second conductive wiring M2 may extend in the first direction D1 or the second direction D2. Accordingly, the second conductive wiring M2 to extend long in the second insulating film structure 202. Although not shown, the via is formed on the second conductive wiring M2 to electrically connect the second conductive wiring M2 to a third conductive wiring M3, as described below.

The second conductive wiring M2 may include a conductive material. For example, the second conductive wiring M2 may include, but not limited to, one or more metals such as tungsten (W), titanium (Ti), tantalum (Ta), copper (Cu), and aluminum (Al). For convenience of explanation, the following description will be given assuming that the second conductive wiring M2 includes copper (Cu).

Although not shown, the second conductive wiring M2 may be connected to various internal circuit elements in the substrate 100. Thus, the second conductive wiring M2 may be used to configure the circuit of the semiconductor device 10 according to some example embodiments.

A third insulating film structure 203 may be formed on the second insulating film structure 202 and the second conductive wiring M2. Although the third insulating film structure 203 is shown as being formed directly on the second insulating film structure 202, this is only for convenience of explanation. For example, it goes without saying that other etch stop films and/or conductive patterns may be interposed between the third insulating film structure 203 and the second insulating film structure 202.

The third insulating film structure 203 may include, for example, at least one of silicon oxide, silicon nitride, silicon oxynitride, a low-k material having a dielectric constant lower than that of silicon oxide, or a combination thereof. The low-k material may include, for example, but not limited to, at least one of FOX (Flowable Oxide), TOSZ (Torene SilaZene), USG (Undoped Silica Glass), BSG (Borosilica Glass), PSG (PhosphoSilica Glass), BPSG (BoroPhosphoSilica Glass), PETEOS (Plasma Enhanced Tetra Ethyl Ortho Silicate), FSG (Fluoride Silicate Glass), CDO (Carbon Doped silicon Oxide), Xerogel, Aerogel, Amorphous Fluorinated Carbon, OSG (Organo Silicate Glass), Parylene, BCB (bis-benzocyclobutenes), SiLK, polyimide, porous polymeric material, or combinations thereof.

The third conductive wiring M3 may be formed in the third insulating film structure 203. For example, the third conductive wiring M3 may extend in the first direction D1 or the second direction D2. Accordingly, the third conductive wiring M3 may extend long inside the third insulating film structure 203. Although not shown, the via is formed on the third conductive wiring M3 to electrically connect the third conductive wiring M3 to a fourth conductive wiring M4 as described below.

The third conductive wiring M3 may include a conductive material. For example, the third conductive wiring M3 may include, but not limited to, one or more metals such as tungsten (W), titanium (Ti), tantalum (Ta), copper (Cu), and aluminum (Al). For convenience of explanation, the following description will be given assuming that the third conductive wiring M3 includes copper (Cu).

Although not shown, the third conductive wiring M3 may be connected to various internal circuit elements in the substrate 100. Thus, the third conductive wiring M3 may be used to configure the circuit of the semiconductor device 10 according to some example embodiments.

A fourth insulating film structure 204 may be formed on the third insulating film structure 203 and the third conductive wiring M3. The fourth insulating film structure 204 is shown as being formed directly on the third insulating film structure 203, but this is only for convenience of explanation. For example, it goes without saying that other etch stop films and/or conductive patterns may be interposed between the fourth insulating film structure 204 and the third insulating film structure 203. The fourth insulating film structure 204 may surround the upper and side faces of the fourth conductive wiring M4.

The fourth insulating film structure 204 may include, for example, at least one of silicon oxide, silicon nitride, silicon oxynitride, a low dielectric constant material having a dielectric constant lower than that of silicon oxide, or combinations thereof. The low dielectric constant material may include, for example, but not limited to, at least one of FOX (Flowable Oxide), TOSZ (Torene SilaZene), USG (Undoped Silica Glass), BSG (Borosilica Glass), PSG (PhosphoSilica Glass), BPSG (BoroPhosphoSilica Glass), PETEOS (Plasma Enhanced Tetra Ethyl Ortho Silicate), FSG (Fluoride Silicate Glass), CDO (Carbon Doped silicon Oxide), Xerogel, Aerogel, Amorphous Fluorinated Carbon, OSG (Organo Silicate Glass), Parylene, BCB (bis-benzocyclobutenes), SiLK, polyimide, porous polymeric material, or combinations thereof.

The fourth insulating film structure 204 may include a first interlayer insulating film 214, a second interlayer insulating film 224, and a third interlayer insulating film 234, which are sequentially stacked. The first interlayer insulating film 214 may be disposed on the third insulating film structure 203. The first interlayer insulating film 214 may be in direct contact with the third insulating film structure 203, but is not limited thereto. As another example, another interlayer insulating film and/or conductive pattern may be interposed between the first interlayer insulating film 214 and the third insulating film structure 203.

The second interlayer insulating film 224 may be disposed on the first interlayer insulating film 214. The third interlayer insulating film 234 may be disposed on the second interlayer insulating film 224. The first interlayer insulating film 214 and the third interlayer insulating film 234 may include silicon oxide, and the second interlayer insulating film 224 may include silicon nitride, but example embodiments are not limited thereto.

The fourth insulating film structure 204 may include a via hole 204_H that exposes at least a part of the fourth conductive wiring M4. For example, the fourth insulating film structure 204 may include a via hole 204_H that exposes at least a part of the second metal layer 402. The via hole 204_H may include a shape that is nearly vertical on the basis of the first direction D1. In other words, the slope of the via hole 204_H with respect to the third direction D3 may be close to zero.

By adjusting the slope of the via hole 204_H with respect to the third direction D3 to be equal to or greater than 0° and equal to less than or 90°, the resistance generated during contact formation may be reduced. Therefore, the operating speed of the element may be improved, the width of the wiring may be reduced, and the semiconductor device may be more highly integrated.

The fourth conductive wiring M4 may be formed inside the fourth insulating film structure 204. For example, the fourth conductive wiring M4 may extend in the first direction D1 or the fourth direction D2. Accordingly, the fourth conductive wiring M4 may extend long inside the fourth insulating film structure 204.

The fourth conductive wiring M4 may include a conductive material. For example, the fourth conductive wiring M4 may include, but not limited to, one or more metals such as tungsten (W), titanium (Ti), tantalum (Ta), copper (Cu), and aluminum (Al).

The fourth conductive wiring M4 may include a first metal layer 401, a second metal layer 402, and a wiring capping layer 403, which are sequentially stacked. For example, the second metal layer 402 may be disposed between the first metal layer 401 and the wiring capping layer 403.

The first metal layer 401, the second metal layer 402, and the wiring capping layer 403 may include a metal material. For example, the first metal layer 401 may include titanium (Ti), and the second metal layer 402 may include aluminum (Al).

The wiring capping layer 403 may absorb light at the time of an exposure process to the photoresist film to reduce or prevent light reflection. The wiring capping layer 403 may include, but not limited to, at least one of titanium (Ti), zinc (Zn), aluminum (Al), magnesium (Mg), or cerium (Ce).

A thickness L1 of the first metal layer 401 may be smaller than a thickness L2 of the second metal layer 402.

Although not shown, the fourth conductive wiring M4 may be connected to various internal circuit elements in the substrate 100. Thus, the fourth conductive wiring M4 may be used to configure the circuit of the semiconductor device 10 according to some embodiments.

A redistribution barrier film 213 may be disposed on the upper face of the fourth insulating film structure 204 and on a side wall 204s of the via hole 204_H. The redistribution barrier film 213 may include a conductive material such as aluminum (Al), copper (Cu), silver (Ag), tin (Sn), gold (Au), nickel (Ni), lead (Pb), titanium (Ti) or an alloy thereof. The redistribution barrier film 213 may be disposed between the fourth insulating film structure 204 and a redistribution conductive layer 211 to be described below.

The redistribution conductive layer 211 may include a first region 211_1, a second region 211_2, and a third region 211_3. The first region 211_1 is in contact with and electrically connected to the upper face of the fourth conductive wiring M4. The second region 211_2 is disposed along the upper face of the fourth insulating film structure 204. The third region 211_3 may extend between the first region 211_1 and the second region 211_2 to electrically connect the first region 211_1 and the second region 211_2.

The first region 211_1 may include a pad region 211a and a wiring region 211b. The pad region 211a may be disposed inside the wiring capping layer 403. For example, the pad region 211a may be in direct contact with at least a part of the second metal layer 402. The pad region 211a includes a shape protruding in a convex shape toward the wiring capping layer 403. The wiring region 211b may be disposed along the profile of the redistribution barrier film 213.

A thickness L4 of a portion of the wiring region 211b disposed on the upper face 204U of the fourth insulating film structure 204 may not be uniform. The thickness L4 of the wiring region 211b disposed on the upper face 204U of the fourth insulating film structure 204 may be adjusted depending on the resistance desired or required for the product. A thickness L3 of the redistribution barrier film 213 may be adjusted depending on the reliability desired or required for the product.

The redistribution conductive layer 211 may be in contact with and electrically connected to the fourth conductive wiring M4 through the via hole 204_H disposed in the fourth insulating film structure 204. That is to say, the redistribution conductive layer 211 and the fourth conductive wiring M4 may be in contact with and are electrically connected to each other through the via hole 204_H included in the fourth insulating film structure 204.

The redistribution conductive layer 211 may include a conductive material such as aluminum (Al), copper (Cu), silver (Ag), tin (Sn), gold (Au), nickel (Ni), lead (Pb), titanium (Ti) or an alloy thereof, and may be formed using a physical vapor deposition (PVD), a chemical vapor deposition (CVD), a plasma enhanced CVD, or an atomic layer deposition damascene, an electroplate and the like. For example, the redistribution conductive layer 211 may be formed by a sputtering method of physical vapor deposition (PVD). However, the inventive concepts are not limited to the above examples.

The passivation layer 230 may include a first portion 210 and a second portion 220. The first portion 210 of the passivation layer 230 may cover the fourth insulating film structure 204 and the redistribution conductive layer 211. The second portion 220 of the passivation layer 230 may fill a second trench 211t to be described below.

At least a part of the second region 211_2 of the redistribution conductive layer 211 may be exposed. The redistribution bump 212 is disposed while being in contact with an upper face of the second region 211_2, and the redistribution conductive layer 211 is electrically connected to the fourth conductive wiring M4 through the redistribution bump 212 and the second region 211_2.

The redistribution bump 212 may include a redistribution under bump metallization (UBM) 212_1 and a redistribution paste 212_2. The redistribution UBM 212_1 may function as an adhesion layer, a diffusion barrier layer, and/or a wetting layer, and some regions may be exposed by the passivation layer 230. The redistribution UBM 212_1 may be formed as a Cr/Cr-Cu/Cu, TiW/Cu, Al/NiV/Cu, Ti/Cu, Ti/Ni, Ni/Au, or Ti/Cu/Ni, Ti/Ni/Cu structure. The redistribution UBM 212_1 may be used, for example, as a seed layer in a subsequent plating process.

The redistribution paste 212_2 is a conductive paste, and may be, for example, a solder paste or a metal paste. For example, the redistribution paste 212_2 may include, for example, a tin-silver (Sn—Ag) alloy or tin (Sn).

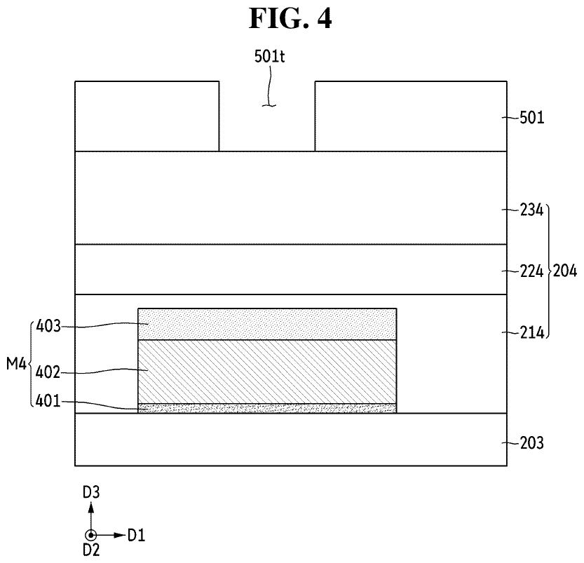

FIGS. 4 to 11 are diagrams for explaining intermediate stages of a method for manufacturing a semiconductor device according to an example embodiment of the present inventive concepts. For reference, FIGS. 4 to 11 are diagrams for explaining intermediate steps of the method for manufacturing the semiconductor device in which the region R2 of FIG. 2 is enlarged. For convenience of explanation, FIGS. 4 to 11 will be mainly explained on the points different from those explained in FIGS. 1 to 3.

Referring to FIG. 4, a first mask pattern 501 is formed on the fourth insulating film structure 204. The first mask pattern 501 may include a first opening 501t that exposes at least a part of the fourth insulating film structure 204. Specifically, the first mask pattern 501 may include a first opening 501t that exposes at least a part of the third interlayer insulating film 234.

The first mask pattern 501 may include a soft mask such as a photoresist (PR) or a hard mask such as a silicon nitride film and/or SiO₂.

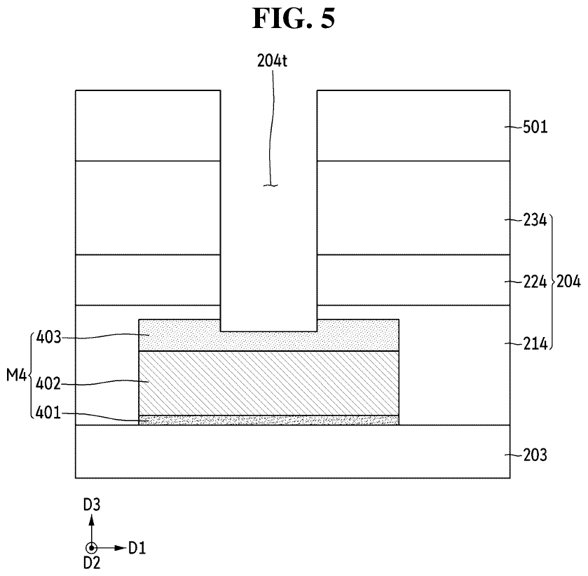

Referring to FIG. 5, a first trench 204t is formed using the first mask pattern 501. For example, the third interlayer insulating film 234 exposed in the first opening 501t is etched using the first mask pattern 501, and the second interlayer insulating film 224 and the first interlayer insulating film 214 are etched in sequence.

The first interlayer insulating film 214, the second interlayer insulating film 224, and the third interlayer insulating film 234 are etched to expose at least a part of the wiring capping layer 403. For example, a part of the wiring capping layer 403 exposed at the lower part of the first interlayer insulating film 214 (e.g., a part of the wiring capping layer 403 exposed through the first interlayer insulating film 214) is etched. Dry etching is used to etch the first interlayer insulating film 214, the second interlayer insulating film 224, the third interlayer insulating film 234, and the wiring capping layer 403.

By etching the first interlayer insulating film 214, the second interlayer insulating film 224, the third interlayer insulating film 234, and the wiring capping layer 403 by dry etching, the slope of the first trench 204t with respect to the third direction D3 is formed to be nearly vertical, compared to a case where the first interlayer insulating film 214, the second interlayer insulating film 224, the third interlayer insulating film 234, and the wiring capping layer 403 are etched using the wet etching.

In addition, by etching the first interlayer insulating film 214, the second interlayer insulating film 224, the third interlayer insulating film 234, and the wiring capping layer 403 by the dry etching, the etching residue generated during the etching process may be reduced compared to a case where the wet etching is used. The etching residue may include, for example, aluminum (Al) polymer. Because the amount of etching residue is reduced, it becomes easier to remove the etching residue, and thus, performance and/or reliability of the semiconductor element is improved.

By etching the first interlayer insulating film 214, the second interlayer insulating film 224, the third interlayer insulating film 234, and the wiring capping layer 403 at once, etching residue generated during the etching process may be reduced. The etching residue may include, for example, aluminum (Al) polymer.

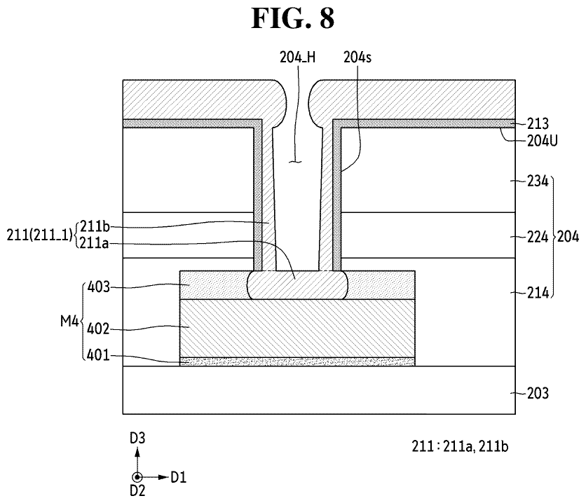

Because the by-products generated during the etching process decreases, the amount of the redistribution conductive layer (see 211 of FIG. 8) to be formed thereafter may be reduced, thereby reducing the manufacturing cost of the semiconductor device.

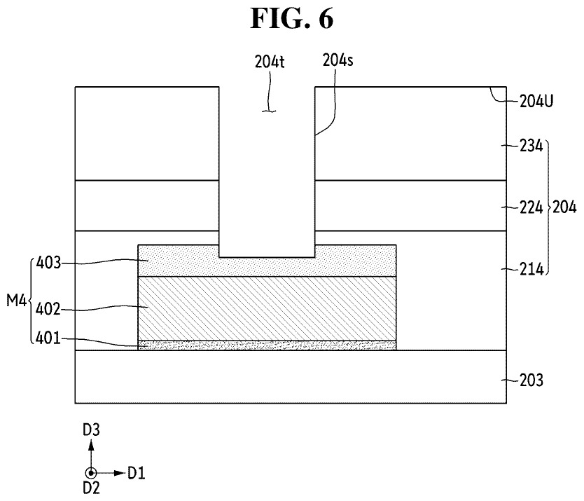

Referring to FIG. 6, the first mask pattern 501 is removed. For example, the first mask pattern 501 may be removed through an ashing process or a strip process. For example, the first mask pattern 501 may be removed by the ashing process, thereby reducing or minimizing oxidation of the fourth insulating film structure 204.

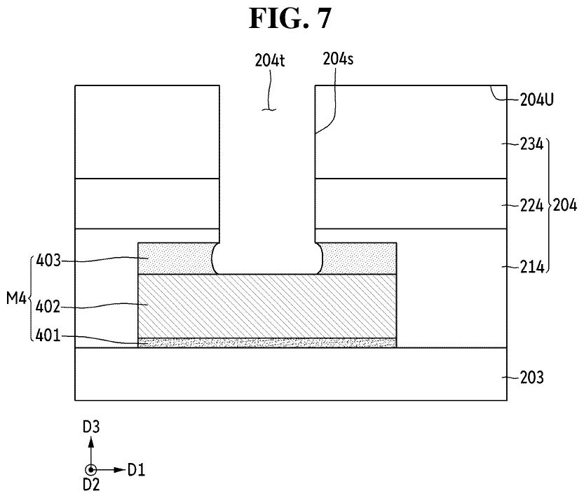

Referring to FIG. 7, a part of the wiring capping layer 403 is etched. For example, the wiring capping layer 403 is etched, using the wet etching. Accordingly, the first trench 204t may be formed in the wiring capping layer 403 to have a convex shape toward the wiring capping layer 403.

Referring to FIG. 8, the redistribution barrier film 213 and the redistribution conductive layer 211 are formed. For example, the redistribution barrier film 213 is formed along the upper face 204U of the fourth insulating film structure 204 and the side wall 204s of the first trench 204t. The wiring region 211b is formed along the profile of the redistribution barrier film 213. The pad region 211a is formed to fill the first trench 204t formed in the wiring capping layer 403.

The upper face of the pad region 211a may be formed to be coplanar with the upper face of the wiring capping layer 403, but is not limited thereto. As another example, the upper face of the pad region 211a may not be coplanar with the upper face of the wiring capping layer 403.

Although FIG. 8 shows that the redistribution barrier film 213 and the redistribution conductive layer 211 are formed in a single step, but is not limited thereto. As another example, the redistribution conductive layer 211 may be formed on the redistribution barrier film 213, after the redistribution barrier film 213 is formed.

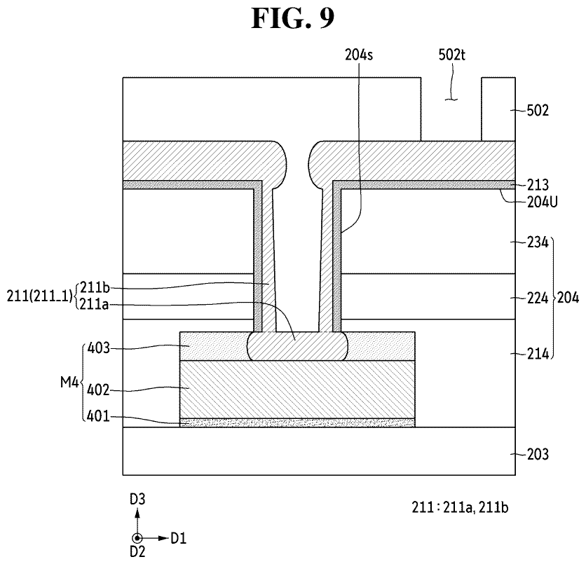

Referring to FIG. 9, a second mask pattern 502 is formed. For example, the second mask pattern 502 is formed to cover the upper face of the redistribution conductive layer 211. The second mask pattern 502 may include a second opening 502t that exposes at least a part of the redistribution conductive layer 211.

The second mask pattern 502 may include, for example, a soft mask such as a photoresist (PR) or a hard mask such as a silicon nitride film and/or SiO₂.

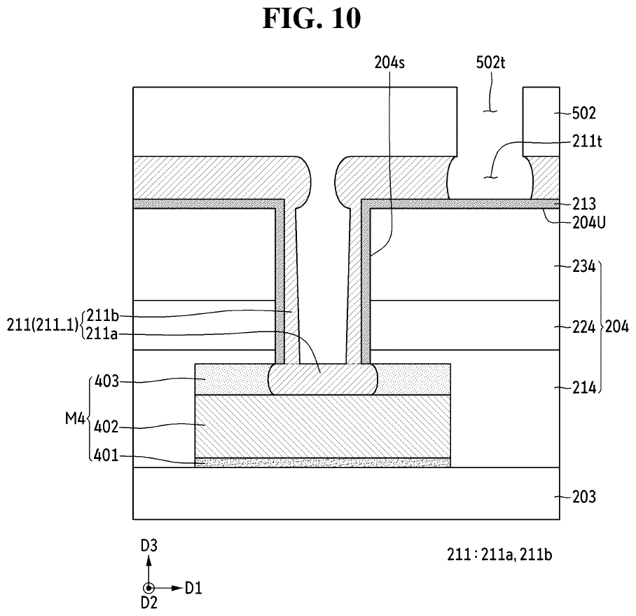

Referring to FIG. 10, a part of the conductive wiring 211 exposed by the second opening 502t of the second mask pattern 502 is removed. In other words, a part of the redistribution conductive layer 211 exposed by the second opening 502t is etched. The redistribution conductive layer 211 is etched using the wet etching.

The redistribution conductive layer 211 is etched to expose at least a part of the upper face of the redistribution barrier film 213. A part of the redistribution conductive layer 211 is etched to form a second trench 211t.

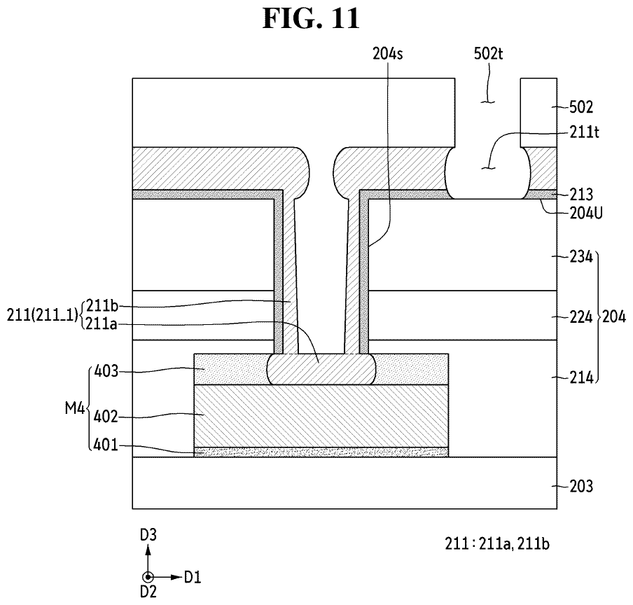

Referring to FIG. 11, the second trench 211t is formed deeper by etching an exposed portion of the redistribution barrier film 213, using the second mask pattern 502. The deepened second trench 211t may be referred to as a wiring trench. For example, a part of the redistribution barrier film 213 exposed by the second opening 502t is etched, using the second mask pattern 502. The redistribution barrier film 213 is etched, using the wet etching.

A part of the redistribution barrier film 213 is etched to expose at least a part of the upper face 204U of the fourth insulating film structure 204.

Referring to FIG. 3, the second mask pattern 502 is removed. For example, the second mask pattern 502 may be removed through an ashing process or a strip process. For example, the second mask pattern 502 may be removed by the ashing process using carbon monoxide (CO) gas or carbon dioxide (CO₂) gas to reduce or minimize oxidation of the fourth insulating film structure 204.

Referring to FIG. 2, a passivation layer 230 is formed on the redistribution conductive layer 211 and the fourth insulating film structure 204. The second portion 220 that fills the wiring trench 211t is formed, and the first portion 210 is formed on the redistribution conductive layer 211 and the fourth insulating film structure 204.

In concluding the detailed description, those skilled in the art will appreciate that many variations and modifications may be made to the disclosed example embodiments without substantially departing from the principles of the present inventive concepts. Therefore, the disclosed example embodiments of the inventive concepts are used in a generic and descriptive sense only and not for purposes of limitation.

What is claimed is:

1. A manufacturing method of a semiconductor device, comprising:
forming a conductive wiring on a substrate in a first direction, the conductive wiring including a metal layer and a wiring capping layer that are sequentially stacked;
forming an insulating film structure to surround an upper face and a side face of the conductive wiring;
forming a first mask pattern including a first opening on the insulating film structure, the first opening overlapping the conductive wiring in a vertical direction;
forming a first trench to expose the wiring capping layer in the insulating film structure, using the first mask pattern as a mask;
removing the exposed wiring capping layer using wet etching to expose at least a part of the metal layer;
forming a redistribution conductive wiring, the redistribution conductive wiring including a pad region and a wiring region, the pad region covering the part of the metal layer exposed in the removing, the wiring region extending along a side wall of the first trench and the upper face of the insulating film structure;
forming a second mask pattern including a second opening on the redistribution conductive wiring, the second opening exposing a part of the wiring region of the redistribution conductive wiring; and
etching the part of the wiring region of the redistribution conductive wiring exposed by the second opening to form a second trench in the redistribution conductive wiring.

2. The manufacturing method of the semiconductor device of claim 1, further comprising:
removing the first mask pattern after forming the first trench.

3. The manufacturing method of the semiconductor device of claim 2, further comprising:
forming a redistribution barrier film extending along the side wall of the first trench and the upper face of the insulating film structure, after removing the first mask pattern.

4. The manufacturing method of the semiconductor device of claim 1, further comprising:
removing the second mask pattern, after forming the second trench.

5. The manufacturing method of the semiconductor device of claim 1,
wherein the wiring capping layer includes at least one of titanium (Ti), zinc (Zn), aluminum (Al), magnesium (Mg), or cerium (Ce).

6. The manufacturing method of the semiconductor device of claim 1,
wherein the insulating film structure includes a first insulating film, a second insulating film, and a third insulating film that are sequentially stacked.

7. The manufacturing method of the semiconductor device of claim 6,
wherein the first insulating film and the third insulating film include silicon oxide, and the second insulating film includes silicon nitride.

8. The manufacturing method of the semiconductor device of claim 1,
wherein the metal layer includes a first metal layer and a second metal layer that are sequentially stacked in the first direction,
the first metal layer includes titanium (Ti), and
the second metal layer is between the first metal layer and the wiring capping layer.

9. The manufacturing method of the semiconductor device of claim 8,
wherein a thickness of the first metal layer in the first direction is smaller than a thickness of the second metal layer in the first direction.

10. The manufacturing method of the semiconductor device of claim 1,
wherein the pad region includes a convex shape in a direction toward the wiring capping layer.

11. The manufacturing method of the semiconductor device of claim 1,
wherein the forming the first trench includes etching the insulating film structure using a dry etching to form the first trench.

12. The manufacturing method of the semiconductor device of claim 1,
wherein the conductive wiring includes copper (Cu).

13. A semiconductor device comprising:
a substrate;
a conductive wiring on the substrate;
an insulating film structure on the substrate, the insulating film structure surrounding an upper face and a side face of the conductive wiring;
a first trench in the insulating film structure, the first trench exposing at least a part of the conductive wiring;
a first redistribution conductive wiring extending along the upper face of the conductive wiring; and
a second redistribution conductive wiring extending along a side wall of the first trench and an upper face of the insulating film structure,
wherein the first redistribution conductive wiring includes a convex shape in a direction toward the conductive wiring.

14. The semiconductor device of claim 13,
wherein the insulating film structure includes a first insulating film, a second insulating film, and a third insulating film that are sequentially stacked in a first direction, and
the first insulating film and the third insulating film include silicon oxide, and the second insulating film includes silicon nitride.

15. The semiconductor device of claim 13, further comprising:
a redistribution barrier film being between the insulating film structure and the second redistribution conductive wiring.

16. The semiconductor device of claim 15,
wherein a thickness of the redistribution barrier film is smaller than a thickness of the second redistribution conductive wiring.

17. The semiconductor device of claim 13,
wherein the conductive wiring includes metal layers that are sequentially stacked in a first direction, and a wiring capping layer is on the metal layers.

18. The semiconductor device of claim 17,
wherein the metal layers include a first metal layer and a second metal layer that are sequentially stacked in the first direction,
the first metal layer includes titanium (Ti),
the second metal layer is between the first metal layer and the wiring capping layer, and
a thickness of the first metal layer is smaller than a thickness of the second metal layer.

19. The semiconductor device of claim 17,
wherein the wiring capping layer includes at least one of titanium (Ti), zinc (Zn), aluminum (Al), magnesium (Mg), or cerium (Ce).

20. A manufacturing method of a semiconductor device, comprising:
forming a conductive wiring on a substrate in a first direction, the conductive wiring including a metal layer and a wiring capping layer that are sequentially stacked in the first direction;
forming an insulating film structure to surround an upper face and a side face of the conductive wiring;
forming a first mask pattern including a first opening on the insulating film structure, the first opening overlapping the conductive wiring in a vertical direction;
forming a first trench to expose the wiring capping layer inside the insulating film structure, using the first mask pattern as a mask;
removing the first mask pattern;
forming a redistribution barrier film extending along a side wall of the first trench and the upper face of the insulating film structure;
removing the exposed wiring capping layer using wet etching to expose at least a part of the metal layer;
forming a redistribution conductive wiring, the redistribution conductive wiring including a pad region and a wiring region, the pad region covering the part of the metal layer exposed in the removing the exposed wiring capping layer, the wiring region extending along the side wall of the first trench and the upper face of the insulating film structure;
forming a second mask pattern including a second opening on the redistribution conductive wiring, the second opening exposing a part of the wiring region of the redistribution conductive wiring;
etching the part of the wiring region of the redistribution conductive wiring exposed in the forming the second mask pattern to form a second trench in the redistribution conductive wiring; and
removing the second mask pattern.
